(19) United States
(12) Patent Application Publication
(10) Pub. No.: US 2024/0194568 A1
(43) Pub. Date: Jun. 13, 2024

(54) SUBSTRATE AND SEMICONDUCTOR DEVICE INCLUDING THE SAME

(71) Applicant: SAMSUNG ELECTRONICS CO., LTD., SUWON-SI (KR)

(72) Inventors: JI SOO HWANG, Suwon-si (KR); JUN SO PAK, Suwon-si (KR); HEE SEOK LEE, Suwon-si (KR); WOO BIN JUNG, Suwon-si (KR)

(21) Appl. No.: 18/514,715

(22) Filed: Nov. 20, 2023

(30) Foreign Application Priority Data
Dec. 13, 2022 (KR) 10-2022-0173265
Jun. 9, 2023 (KR) 10-2023-0074143

(51) Int. Cl. H01L 23/48; H01L 23/498

(52) U.S. Cl. CPC H01L 23/481; H01L 23/49816

(57) ABSTRACT

A substrate includes a first layer including a first power line extending in a first direction and a second power line extending in the first direction, and a second layer disposed under the first layer. The second layer includes a third power line extending in a second direction different from the first direction, and a fourth power line extending in the second direction, a first via electrically connecting the first power line and the third power line to each other, and a second via electrically connecting the second power line and the fourth power line to each other. A first voltage is transferred via the third power line, the first via, and the first power line, and a second voltage is transferred via the fourth power line, the second via, and the second power line.

### CROSS-REFERENCE TO RELATED APPLICATIONS

This application claims priority under 35 U.S.C. § 119 to Korean Patent Application No. 10-2022-0173265 filed on Dec. 13, 2022, and Korean Patent Application No. 10-2023-0074143 filed on Jun. 9, 2023, the disclosures of which are incorporated by reference herein in their entireties.

### TECHNICAL FIELD

Embodiments of the present disclosure relate to a substrate and a semiconductor device including the same.

### DISCUSSION OF RELATED ART

A processor for a mobile device in which low power and high efficiency are factors taken into consideration may include a plurality of power domains that receive operating voltages of different levels and a plurality of cores respectively installed in the power domains.

To reduce heat generation and improve timing characteristics, a plurality of cores installed in the same power domain may be spaced apart from each other. Since the plurality of cores are spaced apart from each other, a configuration of a power delivery network (PDN) that supplies power to each of the cores may become complex. For example, the power delivery network may be configured in a form of a plane. In this case, even when the cores spaced apart from each other are connected to each other, power integrity (PI) may vary due to various factors.

### SUMMARY

Embodiments of the present disclosure provide a substrate with improved power integrity, and a semiconductor device with improved power integrity.

According to an embodiment of the present disclosure, a substrate includes a first layer including a first power line extending in a first direction and a second power line extending in the first direction, and a second layer disposed under the first layer. The second layer includes a third power line extending in a second direction different from the first direction, and a fourth power line extending in the second direction. The substrate further includes a first via electrically connecting the first power line and the third power line to each other, and a second via electrically connecting the second power line and the fourth power line to each other. A first voltage is transferred via the third power line, the first via, and the first power line, and a second voltage is transferred via the fourth power line, the second via, and the second power line.

According to an embodiment of the present disclosure, a substrate includes a first layer including a first power line extending in a first direction and that transmits a first voltage, and a second power line extending in the first direction and that transmits a second voltage, and a second layer disposed under the first layer. The second layer includes a third power line extending in a second direction different from the first direction, and a fourth power line extending in the second direction. The substrate further includes a first via electrically connecting the first power line and the third power line to each other, a second via electrically connecting the second power line and the fourth power line to each other, a first bump disposed on an upper surface of the first layer and electrically connected to the first power line, and a second bump disposed on the upper surface of the first layer and electrically connected to the second power line. The first layer further includes a fifth power line that transmits the first voltage. The first power line, the second power line, and the fifth power line are sequentially arranged in a line along the first direction. The first power line and the fifth power line are connected to each other via a connection line. The connection line has a meandering shape bypassing the second power line. The first power line is disposed on one side of the fifth power line, and a die-side capacitor is disposed on another side of the fifth power line. The die-side capacitor is electrically connected to the first power line via the fifth power line and the connection line.

According to an embodiment of the present disclosure, a semiconductor device includes a board having a first area and a second area defined therein, where the first and second areas are distinct from each other, a semiconductor package disposed in the first area, and a power management chip disposed in the second area. The semiconductor package operates using a first voltage and a second voltage different from the first voltage, and the power management chip operates using the first voltage. The board includes a first layer including a first power line extending in a first direction and a second power line extending in the first direction, a second layer disposed under the first layer and including a third power line extending in a second direction different from the first direction and a fourth power line extending in the second direction, a first via electrically connecting the first power line and the third power line to each other, and a second via electrically connecting the second power line and the fourth power line to each other. The first voltage is transferred via the third power line, the first via, and the first power line, and the second voltage is transferred via the fourth power line, the second via, and the second power line.

### BRIEF DESCRIPTION OF DRAWINGS

The above and other aspects and features of the present disclosure will become more apparent by describing in detail illustrative embodiments thereof with reference to the accompanying drawings, in which:

FIG. 1 is a conceptual diagram illustrating a semiconductor device according to some embodiments of the present disclosure;

FIG. 2 is a cross-sectional view illustrating the semiconductor device of FIG. 1;

FIG. 3 is a perspective view illustrating a power delivery network installed in a substrate according to some embodiments of the present disclosure;

FIG. 4 is a plan view illustrating a first layer of FIG. 3;

FIG. 5 is a plan view illustrating a second layer of FIG. 3;

FIG. 6 is a conceptual diagram illustrating a semiconductor device according to some embodiments of the present disclosure;

FIG. 7 is a perspective view illustrating a power delivery network installed in a substrate according to some embodiments of the present disclosure;

FIG. 8 is a conceptual diagram illustrating a semiconductor device according to some embodiments of the present disclosure;

FIG. 9 is a perspective view illustrating a power delivery network installed in a board of a semiconductor device according to some embodiments of the present disclosure;

FIG. 10 is a diagram illustrating a semiconductor device according to some embodiments of the present disclosure;

FIG. 11 is a plan view showing a first layer of the power delivery network implemented in the substrate shown in FIG. 10;

FIG. 12 is a diagram illustrating an arrangement of a plurality of cores in the plan view of FIG. 11; and

FIG. 13 is a plan view showing an example of the first layer of the power delivery network implemented in the substrate as shown in FIG. 10.

### DETAILED DESCRIPTION OF TH EMBODIMENTS

Embodiments of the present disclosure will be described more fully hereinafter with reference to the accompanying drawings. Like reference numerals may refer to like elements throughout the accompanying drawings.

As used herein, the singular forms “a” and “an” are intended to include the plural forms as well, unless the context clearly indicates otherwise.

It will be further understood that the terms “comprise”, “comprising”, “include”, and “including” when used in this specification, specify the presence of the stated features, integers, operations, elements, and/or components, but do not preclude the presence or addition of one or more other features, integers, operations, elements, components, and/or portions thereof.

As used herein, the term “and/or” includes any and all combinations of one or more of the associated listed items. Expression such as “at least one of” when preceding a list of elements may modify an entirety of list of elements and may not modify the individual elements of the list. When referring to “C to D”, this means C inclusive to D inclusive unless otherwise specified.

It will be understood that, although the terms “first”, “second”, “third”, and so on may be used herein to illustrate various elements, components, regions, layers and/or sections, these elements, components, regions, layers and/or sections should not be limited by these terms. These terms are used to distinguish one element, component, region, layer or section from another element, component, region, layer, or section, unless the context clearly indicates otherwise. Thus, a first element, component, region, layer, or section described below could be termed a second element, component, region, layer, or section, without departing from the spirit and scope of the present disclosure.

In addition, it will also be understood that when a first element or layer is referred to as being present “on” or “beneath” a second element or layer, the first element may be disposed directly on or beneath the second element or may be disposed indirectly on or beneath the second element with a third element or layer being disposed between the first and second elements or layers. It will be understood that when an element or layer is referred to as being “connected to”, or “coupled to” another element or layer, it may be directly on, connected to, or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Further, as used herein, when a layer, film, region, plate, or the like may be disposed “on” or “on a top” of another layer, film, region, plate, or the like, the former may directly contact the latter or still another layer, film, region, plate, or the like may be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like may be disposed “below” or “under” another layer, film, region, plate, or the like, the former may directly contact the latter or still another layer, film, region, plate, or the like may be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

In descriptions of temporal relationships, for example, temporal precedent relationships between two events such as “after”, “subsequent to”, “before”, etc., another event may occur therebetween unless “directly after”, “directly subsequent” or “directly before” is not indicated. The features of the various embodiments of the present disclosure may be partially or entirely combined with each other, and may be technically associated with each other or operate with each other. The embodiments may be implemented independently of each other and may be implemented together in an association relationship.

Spatially relative terms, such as “beneath,” “below,” “lower,” “under,” “above,” “upper,” , etc., may be used herein for ease of illustration to illustrate one element or feature's relationship to another element or feature as illustrated in the figures. It will be understood that the spatially relative terms are intended to encompass different orientations of the device in use or in operation, in addition to the orientation depicted in the figures. For example, when the device in the drawings may be turned over, elements described as “below” or “beneath” or “under” other elements or features would then be oriented “above” the other elements or features. Thus, the example terms “below” and “under” may encompass both an orientation of above and below. The device may be otherwise oriented, for example, rotated 90 degrees or at other orientations, and the spatially relative descriptors used herein should be interpreted accordingly.

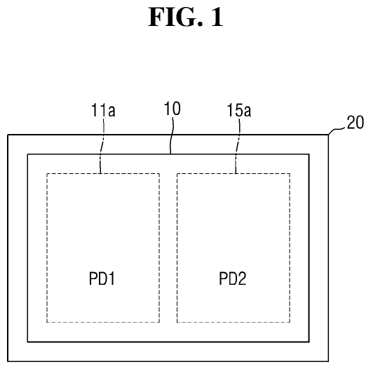

FIG. 1 is a conceptual diagram illustrating a semiconductor device according to some embodiments of the present disclosure.

Referring to FIG. 1, a processor chip 10 may include a plurality of power domains 11a and 15a. The first power domain 11a (PD1) receives a first operating voltage, and the second power domain 15a (PD2) receives a second operating voltage different from the first operating voltage.

The processor chip 10 is disposed on a substrate. The substrate may be, for example, a package substrate 20. Via the substrate 20, the first operating voltage is supplied to the first power domain 11a and the second operating voltage is supplied to the second power domain 15a.

An example in which the processor chip 10 is embodied as a chip disposed on the substrate 20 is described. However, the present disclosure is not limited thereto.

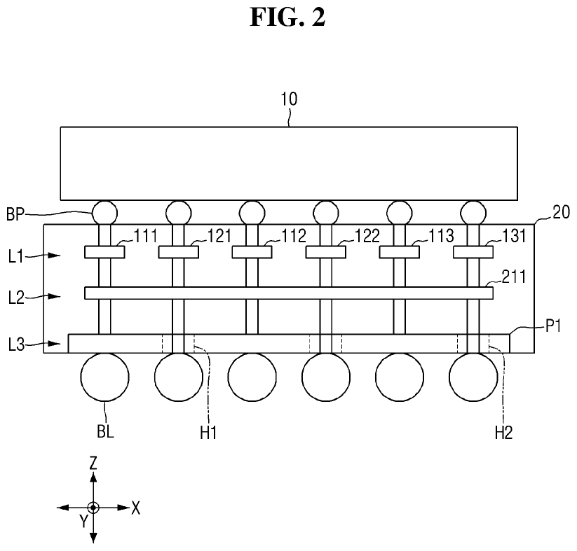

FIG. 2 is a cross-sectional view illustrating the semiconductor device of FIG. 1.

Referring to FIG. 2, the processor chip 10 is disposed on an upper surface of the substrate 20, and the substrate 20 and the processor chip 10 are connected to each other via a bump BP. A ball (or an external connection terminal) BL is disposed on a lower surface of the substrate 20. Instead of the bump BP or the ball BL, other types of members capable of providing electrical connection may be used according to some embodiments.

A power delivery network (PDN) is disposed in the substrate 20 and is configured to respectively provide different operating voltages to the plurality of power domains (for example, 11a and 15a). In some embodiments, some layers of the power delivery network may be constructed in a weave manner rather than a plane manner. The power delivery network may include a plurality of layers L1, L2, and L3. A direction (for example, a Y direction) in which conductive lines 111, 121, 112, 122, 113, and 131 disposed in one layer (for example, L1) may be different from a direction (for example, an X direction) in which a conductive line 211 disposed in another layer (for example, L2) immediately adjacent (or directly adjacent) thereto. The lowest layer (for example, L3) may be in a form of a plane P1. However, the present disclosure is not limited thereto.

The conductive lines 111, 112, and 113, the conductive lines 121 and 122, and the conductive line 131 carry different voltages. For example, a first voltage may be supplied to the conductive lines 111, 112, and 113, a ground voltage may be supplied to the conductive lines 121 and 122, and a second voltage may be supplied to the conductive line 131. In this regard, the conductive lines 111, 112, and 113 may be referred to as first power lines, the conductive line 131 may be referred to as a second power line, and the conductive lines 121 and 122 may be referred to as ground lines.

In this case, the conductive lines 111, 112, and 113 disposed in the layer L1, the conductive line 211 disposed in the layer L2, and the plane P1 may be electrically connected to each other.

Furthermore, the conductive lines 121 and 122 disposed in the layer L1 are not electrically connected to the conductive line 211 and the plane P1. For example, the conductive lines 121 and 122 may extend through a hole H1 formed in the plane P1 and be connected to ball BL through a via.

Furthermore, the conductive line 131 disposed in the layer L1 is not electrically connected to the conductive line 211 and the plane P1. For example, the conductive line 131 may extend through a hole H2 formed in the plane P1 and be connected to the ball BL through a via.

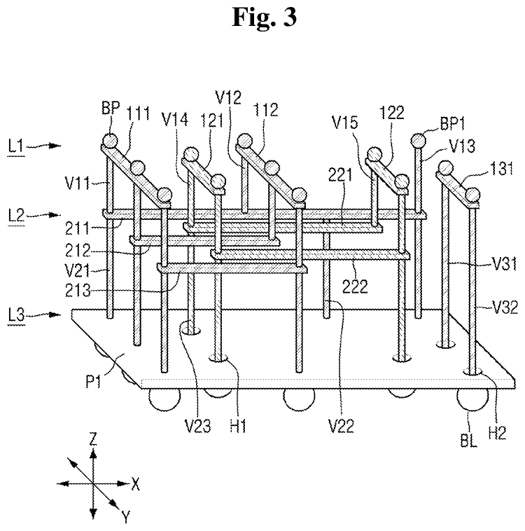

A configuration of the weave-type power delivery network will be described in further detail below with reference to FIGS. 3 to 13.

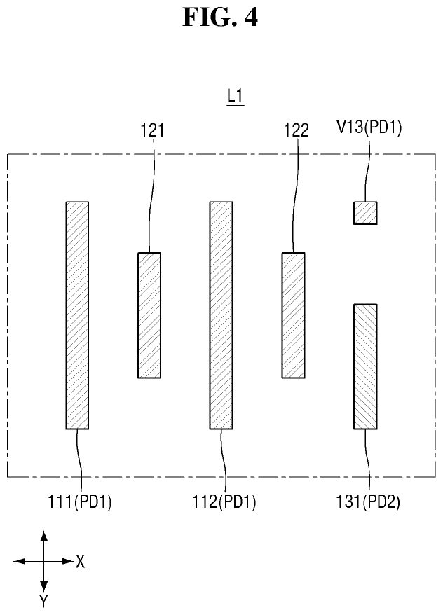

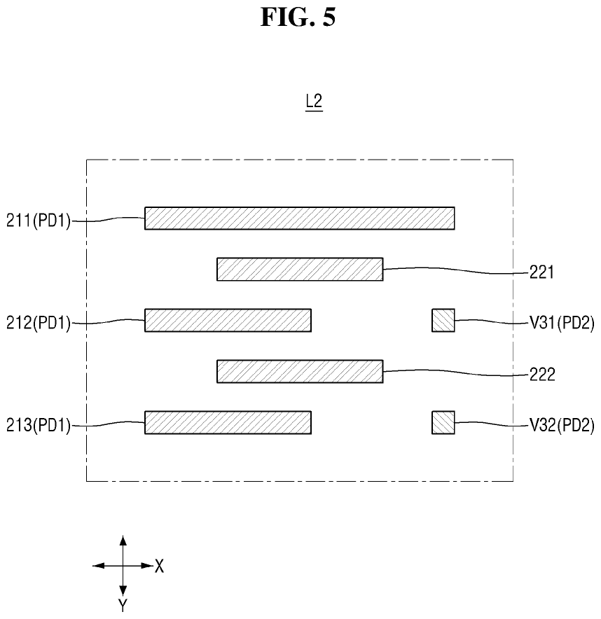

FIG. 3 is a perspective view illustrating a power delivery network installed in a substrate according to some embodiments of the present disclosure. FIG. 4 is a plan view illustrating the first layer L1 of FIG. 3. FIG. 5 is a plan view illustrating the second layer L2 of FIG. 3.

Referring to FIG. 3 to FIG. 5, the power delivery network includes a plurality of layers L1, L2, and L3.

The first layer L1 includes a plurality of conductive lines 111, 121, 112, 122, and 131 extending in the first direction Y and parallel to each other.

The power lines 111 and 112 among the plurality of conductive lines 111, 121, 112, 122, and 131 transmit the first voltage, the power line 131 among the plurality of conductive lines 111, 121, 112, 122, and 131 transmits the second voltage, and the ground lines 121 and 122 among the plurality of conductive lines 111, 121, 112, 122, and 131 transmit a ground voltage VSS. The second voltage may be different from the first voltage and may be a ground voltage. However, the present disclosure is not limited thereto.

The ground line 121 is disposed between adjacent (e.g., directly adjacent) power lines (e.g., 111 and 112), and the ground line 122 is disposed between other adjacent (e.g., directly adjacent) power lines (e.g., 112 and 131).

The second layer L2 includes a plurality of conductive lines 211, 212, 213, 221, and 222 that extend in the second direction X and are parallel to each other. The second direction X and the first direction Y may be orthogonal to each other. However, the present disclosure is not limited thereto.

The power lines 211, 212, and 213 among the plurality of conductive lines 211, 212, 213, 221, and 222 transmit the first voltage, and the ground lines 221 and 222 among the plurality of conductive lines 211, 212, 213, 221, and 222 transmit the ground voltage VSS. The ground line 221 is disposed between adjacent (e.g., directly adjacent) power lines (e.g., 211 and 212), and the ground line 222 is also disposed between other adjacent (e.g., directly adjacent) power lines (e.g., 212 and 213).

The plane P1 may be formed in the third layer L3. However, the present disclosure is not limited thereto. The plane P1 is connected to the first voltage.

Vias V11, V12, V13, V14, and V15 are disposed between the first layer L1 and the second layer L2, and vias V21, V22, and V23 are disposed between the second layer L2 and the third layer L3.

The power line (e.g., 211) of the second layer L2 is electrically connected to at least one power line (e.g., one of 111 and 112) in the first layer L1 through the vias V11 and V12. Furthermore, the power line (e.g., 211) of the second layer L2 is connected to the plane P1 through the vias V21 and V22. Accordingly, the first voltage applied via the ball BL is transferred to the processor chip 10 disposed on the upper surface of the substrate 20 through the vias V21 and V22, the power line 211, and the vias V11, V12 and V13.

Accordingly, the first voltage applied via the ball BL may be transferred to the processor chip 10 disposed on the upper surface of the substrate 20 through the vias V21 and V22, the power line 211, and the vias V11, V12 and V13.

The vias V21, V22, the power line 211, and the vias V11, V12, and V13, etc. constitute a portion of the power delivery network that delivers the first voltage.

The ground line (e.g., 221) of the second layer L2 is electrically connected to at least one ground line (e.g., one of 121 and 122) in the first layer L1 through the vias V14 and V15. Furthermore, the ground line (e.g., 221) of the second layer L2 is connected to the ball BL through the via V23 extending through the hole H1 of the plane P1.

Accordingly, the ground voltage (for example, VSS) applied via the ball BL may be transferred to the processor chip 10 disposed on the upper surface of the substrate 20 through the via V23, the power line 221, and the vias V14 and V15. The via V23, the power line 221, and the vias V14 and V15 constitute a portion of the power delivery network that delivers the ground voltage.

In this way, according to some embodiments, the conductive lines (e.g., 111, 121, 112, 122, and 131) connected to different voltages (e.g., the first voltage, the second voltage, and the ground voltage) are disposed in each layer (e.g., L1). Therefore, the conductive lines (e.g., 111, 121, 112, 122, and 131) extend in one direction (e.g., the first direction Y), which may prevent a short circuit from occurring between the conductive lines.

Furthermore, the conductive lines (e.g., 211, 212, 213, 221, and 222) disposed in another layer (e.g., L2) immediately adjacent (or directly adjacent) to one layer (e.g., L1) may extend in another direction (e.g., the second direction X) different from the one direction (e.g., the first direction Y).

The directions (e.g., the first direction Y and the second direction X) at which the conductive lines respectively disposed in the adjacent (e.g., directly adjacent) layers (e.g., L1 and L2) extend may be different from each other. Thus, the conductive lines respectively disposed in the adjacent layers constitute a weave structure. When the power delivery network is constructed in the weave structure, a power delivery path may be efficiently designed, and design difficulty may be lowered.

Furthermore, in a design process, when a plurality of bumps BP connected to the same voltage are disposed, there may be a bump BP that is spaced apart from the rest of the bumps BP. For example, in FIG. 3, the bumps BP connected to the first voltage are disposed at a left side of FIG. 3, while another bump BP1 is disposed at a right corner in FIG. 3.

Each layer may be constructed in a form of a plane when designing the power delivery network. In this case, the bump BP1 is connected to a corresponding plane via a thin line. Therefore, resistance and inductance of a path from the corresponding ball BL to the bump BP1 may be significantly increased, such that the power integrity of the bump BP1 is deteriorated.

However, according to some embodiments, the power delivery network is designed in the weave shape. Thus, even when the bump BP1 is not directly connected to the conductive line disposed in the first layer L1, the bump BP1 may be directly connected to the conductive line 211 disposed in the second layer L2 through the via V13. Therefore, the resistance and the inductance of the path from the corresponding ball BL to the bump BP1 do not increase. Thus, in embodiments, the power integrity of the bump BP1 does not deteriorate, compared to those of other bumps BP.

In addition, a configuration in which an arrangement of the balls BL disposed on the lower surface of the substrate 20 coincides with an arrangement of the bumps BP in a corresponding domain may contribute to maintaining the power integrity. That is, in a plan view in the third direction Z, a configuration that the balls BL and the bumps BP are arranged to as to overlap each other may contribute to maintaining the power integrity. However, as performance of the processor chip increases, the number of bumps BP increases and a spacing between the bumps BP becomes smaller, which may make it difficult to achieve the configuration that the arrangement of the balls BL coincides with the arrangement of the bumps BP. In this regard, when the power delivery network is designed in a shape of a plane, a ball BL (that is, an independent power ball) to which power is applied independently may be present according to the arrangement of other powers and signals. The independent power ball BL may make it difficult to design the power delivery network and may cause an increase in the number of stacked layers. However, when the power delivery network is designed in the weave shape, it may become easier to connect the bumps BP to each other, thus making it easier to dispose the balls BL at a desired location in a gathered manner.

In one example, in the first layer L1, the conductive line 131 that transmits the second voltage is connected to the ball through the vias V31 and V32. The vias V31 and V32 may extend through the hole H2 of the plane P1 so as to be connected to the corresponding ball BL. As illustrated, the conductive line contacting the vias V31 and V32 may be absent in the second layer L2. In an embodiment, unlike what is illustrated, a separate conductive line may be present in the second layer L2.

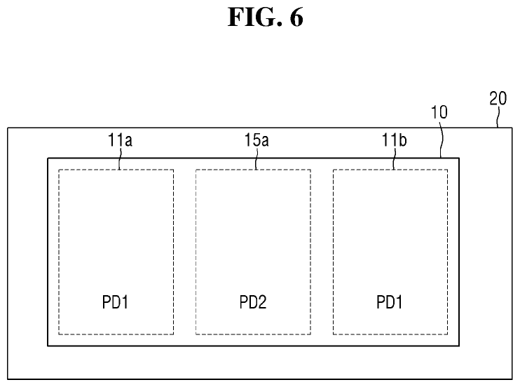

FIG. 6 is a conceptual diagram illustrating a semiconductor device according to some embodiments of the present disclosure. For convenience of explanation, a further description of components and technical aspects previously described will be omitted.

Referring to FIG. 6, the processor chip 10 may include a plurality of power domains 11a, 15a, and 11b. The first power domains 11a and 11b (PD1) receive a first operating voltage, and the second power domain 15a (PD2) receives a second operating voltage different from the first operating voltage.

The processor chip 10 is disposed on the substrate (e.g., the package substrate 20). Via the substrate 20, the first operating voltage is provided to the first power domains 11a and 11b, and the second operating voltage is supplied to the second power domain 15a.

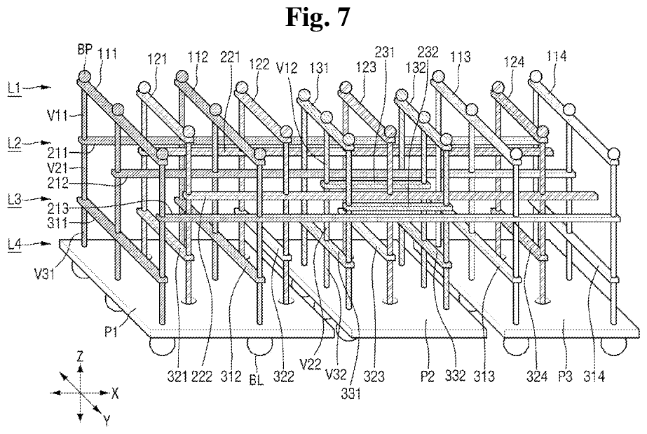

FIG. 7 is a perspective view illustrating a power delivery network installed in a substrate according to some embodiments of the present disclosure. For convenience of explanation, a further description of components and technical aspects previously described will be omitted.

The power delivery network shown in FIG. 3 is composed of three layers, whereas the power delivery network shown in FIG. 7 is composed of four layers. The power delivery network may be implemented to have five or more layers, or the power delivery network may be implemented to have two layers.

Referring to FIG. 7, the power delivery network includes a plurality of layers L1, L2, L3, and L4.

The first layer L1 includes a plurality of conductive lines 111, 121, 112, 122, 131, 123, 132, 113, 124, and 114 that extend in the first direction Y and are parallel to each other.

Among the plurality of conductive lines 111, 121, 112, 122, 131, 123, 132, 113, 124, and 114, the power lines 111, 112, 113, and 114 transmit the first voltage, the power lines 131 and 132 transmit the second voltage different from the first voltage, and the ground lines 121, 122, 123, and 124 deliver the ground voltage VSS. The ground line 121 is disposed between adjacent (e.g., directly adjacent) power lines (e.g., 111 and 112), and the ground line 123 is also disposed between other adjacent (e.g., directly adjacent) power lines (e.g., 131 and 132).

The second layer L2 includes a plurality of conductive lines 211, 212, 213, 221, 222, 231, and 232 extending in the second direction X and parallel to each other.

Among the plurality of conductive lines 211, 212, 213, 221, 222, 231, and 232, the power lines 211, 212, and 213 transmit the first voltage, the power lines 231 and 232 transmit the second voltage, the ground lines 221 and 222 carry the ground voltage VSS. The ground line 221 is disposed between adjacent (e.g., directly adjacent) power lines (e.g., 211 and 212), and the ground line 222 is also disposed between other adjacent (e.g., directly adjacent) power lines (e.g., 212 and 213).

The third layer L3 includes a plurality of conductive lines 311, 321, 312, 322, 331, 321, 332, 313, 324, and 314 that extend in the first direction Y and are parallel to each other.

Among the plurality of conductive lines 311, 321, 312, 322, 331, 321, 332, 313, 324, and 314, the power lines 311, 312, 313, and 314 transmit the first voltage, the power lines 331 and 332 transmit the second voltage, and the ground lines 321, 322, 323, and 324 deliver the ground voltage VSS. The ground line 321 is disposed between adjacent (e.g., directly adjacent) power lines (e.g., 311 and 312), and the ground line 323 is also disposed between other adjacent (e.g., directly adjacent) power lines (e.g., 331 and 332).

Planes P1, P2, and P3 may be disposed in the fourth layer L4. However, the present disclosure is not limited thereto. The planes P1 and P3 are connected to the first voltage, and the plane P2 is connected to the second voltage. Balls BL that receive external power or input/output a signal may be disposed on a lower surface of each of the planes P1, P2, and P3. The planes P1, P2, and P3 may be positioned at the same vertical level.

A via (e.g., V11) is disposed between the first layer L1 and the second layer L2. A via (e.g., V21) is disposed between the second layer L2 and the third layer L3, and a via (e.g., V31) is disposed between the third layer L3 and the fourth layer L4.

For example, the first voltage may be provided to the processor chip 10 via the ball BL disposed under the substrate 20, the plane P1 of the fourth layer L4, the via V31, the power line 311 of the third layer L3, the via V21, the power lines 211, 212, and 213 of the second layer, the via V11, and the power line 111 of the first layer.

In an example, the second voltage may be provided to the processor chip 10 via the ball BL disposed under the substrate 20, the plane P2 of the fourth layer L4, the via V32, the power line 331 of the third layer L3, the via V22, the power lines 231 and 232 of the second layer, the via V12, and the power line 131 of the first layer.

As shown in FIG. 6, in the processor chip 10, the first domains 11a and 11b are separated from each other by the second domain 15a. Even in this case, as shown in FIG. 7, the bumps BP respectively disposed in the first domains 11a and 11b spaced apart from each other may be electrically connected to each other via the conductive lines (e.g., 211, 212, 213, 221, and 222) extending lengthwise in the second direction X. Accordingly, the power integrity may be improved.

In FIGS. 1 to 7, the power delivery network applied to the substrate (the package substrate) has been described. Hereinafter, a power delivery network applied to a board will be described. A design principle of the power delivery network applied to the substrate and a design principle of the power delivery network applied to the board are similar to each other.

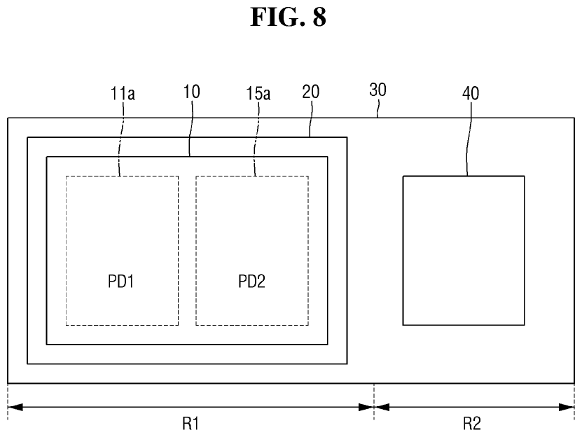

FIG. 8 is a conceptual diagram illustrating a semiconductor device according to some embodiments of the present disclosure. For convenience of explanation, a further description of components and technical aspects previously described will be omitted.

Referring to FIG. 8, the semiconductor device according to some embodiments of the present disclosure includes a board 30, a processor chip 10 and a semiconductor package 20, and a power management chip 40.

The board 30 includes a first area R1 and a second area R2 that are separate and distinct from each other. The processor chip 10 and the semiconductor package 20 are installed in the first area R1 of the board 30. The processor chip 10 may be installed on the semiconductor package 20. The power management chip 40 is installed in the second area R2 of the board 30.

The processor chip 10 and the semiconductor package 20 may operate using different first and second voltages, and the power management chip 40 may operate using the first voltage.

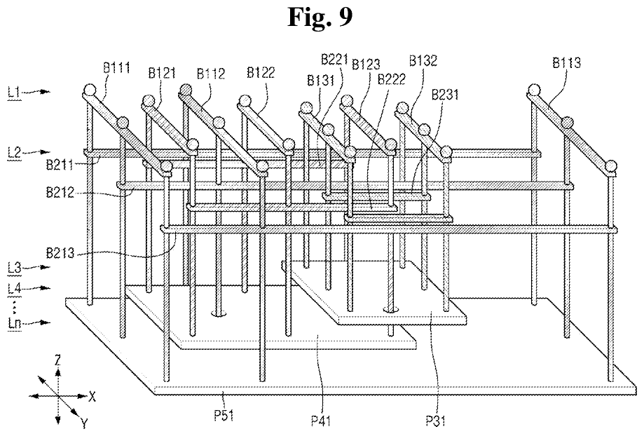

FIG. 9 is a perspective view illustrating a power delivery network installed in a board of a semiconductor device according to some embodiments of the present disclosure. For convenience of explanation, a further description of components and technical aspects previously described will be omitted.

Although the power delivery network shown in FIG. 9 is composed of five layers L1, L2, L3, L4, and Ln, where n is a positive integer, the present disclosure is not limited thereto.

The first layer L1 includes a plurality of conductive lines B111, B121, B112, B122, B131, B123, B132, and B113 extending in the first direction Y and parallel to each other.

Among the plurality of conductive lines B111, B121, B112, B122, B131, B123, B132, and B113, the power lines B111, B112, and B113 transmit the first voltage, the power lines B131 and B132 transmit the second voltage different from the first voltage, and the ground lines B121, B122, and B123 deliver the ground voltage VSS.

The second layer L2 includes a plurality of conductive lines B211, B212, B213, B221, and B222 extending in the second direction X and parallel to each other.

Among the plurality of conductive lines B211, B212, B213, B221, B222, and B231, the power lines B211, B212, and B213 transmit the first voltage, the power line B231 transmits the second voltage different from the first voltage, and the ground lines B221 and B222 transmit the ground voltage VSS. The power lines B211, B212, and B213 extend across the first area (R1 in FIG. 8) and the second area (R2 in FIG. 8).

In the third layer L3, a plane P31 is disposed. The plane P31 is connected to the second voltage. The plane P31 is connected to the power line B231 of the second layer L2 and the power lines B131 and B132 of the first layer L1 through the vias.

In the fourth layer L4, a plane P41 is disposed. The plane P41 is connected to the ground voltage.

In the fifth layer Ln, a plane P51 is disposed. The plane P51 is connected to the first voltage. The fifth layer Ln extends across the first area (R1 in FIG. 8) and the second area (R2 in FIG. 8).

In FIG. 8, the semiconductor package 10 and 20 receives the first voltage and the second voltage, and the power management chip 40 receives the first voltage. Therefore, in the power delivery network configuration as shown in FIG. 9, the first voltage is applied to the semiconductor package 10 and 20 and the power management chip 40 via the plane P51 disposed in the first area (R1 in FIG. 8) and the second area (R2 in FIG. 8). Furthermore, the power lines B211, B212, and B213 extending in the second direction X and across the first area R1 and the second area R2 are formed in the second layer L2. The power lines B211, B212, and B213 are connected to the plane P51 through the via. The power line B113 is formed in the second area R2 and is connected to the power lines B211, B212, and B213 through the vias. This configuration may lower the power integrity.

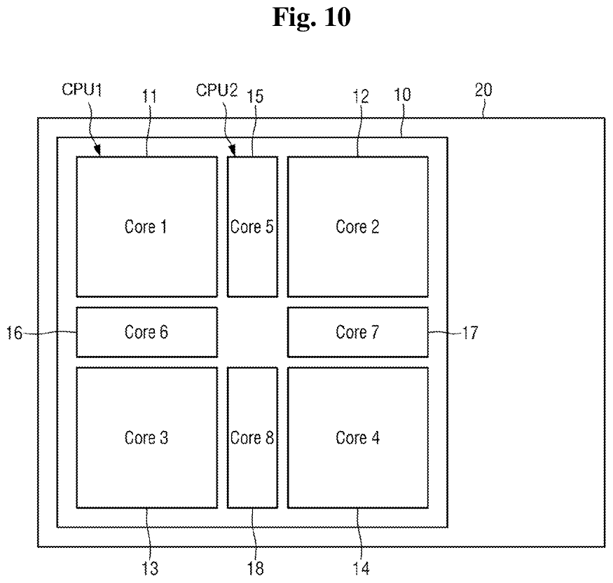

FIG. 10 is a diagram illustrating a semiconductor device according to some embodiments of the present disclosure. For convenience of explanation, a further description of components and technical aspects previously described will be omitted.

Referring to FIG. 10, the processor chip 10 includes a first processor CPU1 and a second processor CPU2. The first processor CPU1 is included in the first power domain (11a of FIG. 1) and the second processor CPU2 is included in the second power domain (15a in FIG. 1).

For example, the first processor CPU1 may be a high-performance processor with high power consumption, and the second processor CPU2 may be a low-performance processor with low power consumption. As shown, the first processor CPU1 includes a plurality of cores 11, 12, 13, and 14, and the second processor CPU2 includes a plurality of cores 15, 16, 17, and 18.

In consideration of heat generation and timing characteristics, the plurality of cores 11, 12, 13, and 14 may be disposed in the first power domain 11a so as to be spaced apart from each other.

Furthermore, each of the cores (e.g., 15) of the second processor CPU2 may be disposed in a space between adjacent (e.g., directly adjacent) cores (e.g., 11 and 12) of the first processor CPU1. Each of the cores (e.g., 16) of the second processor CPU2 may be disposed in a space between adjacent (e.g., directly adjacent) cores (e.g., 11 and 13) of the first processor CPU1.

The processor chip 10 is disposed on the substrate, that is, the package substrate 20. Via the substrate 20, the first operating voltage is provided to the first power domain (11a in FIG. 1), and the second operating voltage is supplied to the second power domain (15a in FIG. 1).

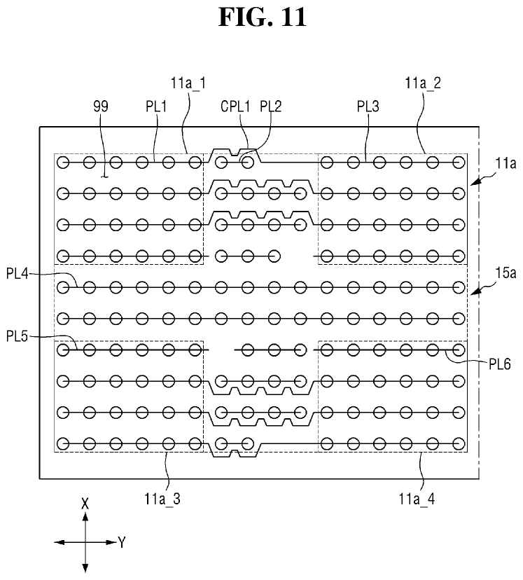

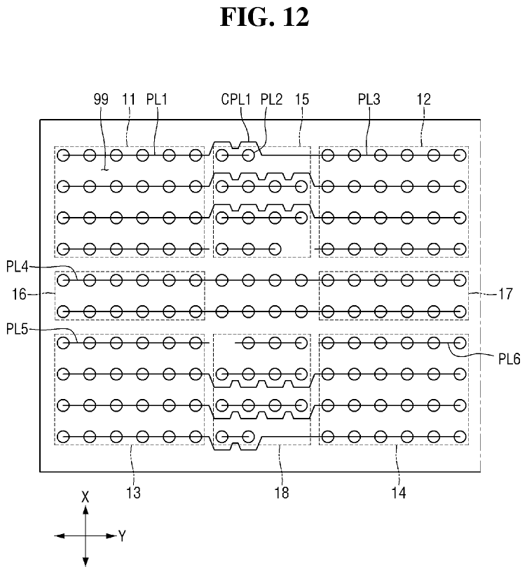

FIG. 11 is a plan view showing the first layer of the power delivery network implemented in the substrate as shown in FIG. 10. FIG. 12 is a diagram illustrating an arrangement of the plurality of cores in the plan view of FIG. 11.

First, referring to FIG. 11, in the first layer, an area where the first power domain 11a is disposed may be divided into four zones 11a_1, 11a_2, 11a_3, and 11a_4 spaced apart from each other. An area where the second power domain 15a is disposed is disposed in a space between adjacent (e.g., directly adjacent) ones of the zones 11a_1, 11a_2, 11a_3, and 11a_4 spaced apart from each other of the first power domain 11a.

As shown, when the four zones 11a_1, 11a_2, 11a_3, and 11a_4 of the first power domain 11a are disposed at an upper left side, an upper right side, a lower left side, and a lower right side, respectively, the area in which the second power domain 15a is disposed may have a “+” shape.

In the first zone 11a_1, a power line PL1 extending in the first direction Y is formed. In the second zone 11a_2, a power line PL3 extending in the first direction Y is formed. In a portion of the second power domain 15a disposed between the first zone 11a_1 and the second zone 11a_2, a power line PL2 extending in the first direction Y is formed. The power lines PL1 and PL3 deliver the first voltage, and the power line PL2 delivers the second voltage.

The power line PL1, the power line PL2 and the power line PL3 are sequentially arranged. The power line PL1, the power line PL2, and power line PL3 are arranged in a row along the first direction Y. As shown, the power line PL1, the power line PL2, and the power line PL3 may be arranged substantially in one straight line.

In this case, the power line PL1 and the power line PL3 are electrically connected to each other via a connection line CPL1. The connection line CPL1 has a meandering shape so as to bypass the power line PL2 such that a short-circuit between the power line PL2 and the connection line CPL1 may be prevented.

As described above, a portion of the second power domain 15a is disposed between the first zone 11a_1 and the third zone 11a_3 of the first power domain 11a. The power line PL1 disposed in the first zone 11a_1, a power line PL5 disposed in the third zone 11a_3, and a power line PL4 disposed in the second power domain 15a are arranged so as to be spaced apart from each other in the second direction X, and extend parallel to each other and extend in the first direction Y.

Furthermore, in the first zone 11a_1 of the first power domain 11a, a plurality of power lines PL1 extending in the first direction Y are disposed, and the plurality of power lines PL1 are arranged so as to be spaced apart from each other in the second direction X and extend parallel to each other. In some embodiments, the ground line is disposed in a space (for example, see reference numeral 99) between adjacent (e.g., directly adjacent) power lines PL1. The ground line may extend along the first direction Y. In each of the other zones 11a_2, 11a_3, and 11a_4 of the first power domain 11a, the ground line extending in the first direction Y may be disposed between adjacent (e.g., directly adjacent) ones of the power lines PL3, between adjacent (e.g., directly adjacent) ones of the power lines PL5, and between adjacent (e.g., directly adjacent) ones of the power lines PL6.

Further, in the second power domain 15a, the ground line extending in the first direction Y may be disposed between adjacent (e.g., directly adjacent) ones of the power lines (for example, PL2).

Furthermore, the ground line extending in the first direction Y may be disposed between the power line (e.g., PL1) installed in the first power domain 11a and the power line (e.g., PL4) installed in the second power domain 15a.

Referring to FIG. 12, the first processor CPU1 is disposed in the first power domain 11a, and the second processor CPU2 is disposed in the second power domain 15a.

In each of the zones (11a_1, 11a_2, 11a_3, and 11a_4 of FIG. 11) spaced apart from each other of the first power domain 11a, each of the cores 11, 12, 13, and 14 of the first processor CPU1 is disposed. In other words, the core 11 is disposed on the power line PL1, the core 12 is disposed on the power line PL3, the core 13 is disposed on the power line PL5, and the core 14 is disposed on the power line PL6.

In the second power domain 15a disposed in the space between adjacent (e.g., directly adjacent) zones (11a_1, 11a_2, 11a_3, and 11a_4 in FIG. 11), each of the cores 15, 16, 17, and 18 of the second processor CPU2 is disposed. For example, the core 15 may be disposed on the power line PL2 and the core 16 may be disposed on the power line PL4.

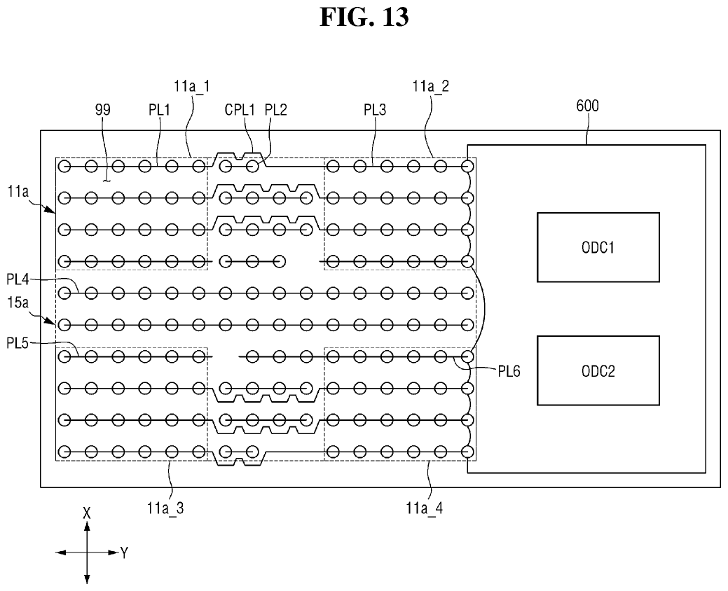

FIG. 13 is a plan view showing an example of the first layer of the power delivery network implemented in the substrate shown in FIG. 10. For convenience of explanation, a further description of components and technical aspects previously described will be omitted.

In the first layer as shown in FIG. 13, the first zone 11a_1 is disposed on one side of the second zone 11a_2 of the first power domain 11a, while capacitors (e.g., die-side capacitors) ODC1 and ODC2 are disposed on the other side of the second zone 11a_2. Alternatively, the third zone 11a_3 is disposed on one side of the fourth zone 11a_4 of the first power domain 11a, while the capacitors ODC1 and ODC2 are disposed on the other side of the fourth zone 11a_4.

As described above, the cores 11, 12, 13, and 14 of the first processor CPU1 are respectively disposed in the zones 11a_1, 11a_2, 11a_3, and 11a_4 spaced apart from each other of the first power domain 11a.

In the first layer L1, the power line PL1 of the first zone 11a_1 and the power line PL3 of the second zone 11a_2 are connected to each other via the connection line CPL1, and the power line PL5 of the third zone 11a_3 and the power line PL6 of the fourth zone 11a_4 are connected to each other via the connection line CPL1. In addition, in the first layer, a plurality of power lines PL1, PL3, PL5, and PL6 formed in the first power domain 11a are arranged in a parallel manner to each other. The plurality of power lines PL1, PL3, PL5, and PL6 arranged in the parallel manner to each other are connected to a plate 600 in which the capacitors ODC1 and ODC2 are disposed.

In other words, the power line PL1 is disposed on one side of the power line PL3, and the capacitors ODC1 and ODC2 are disposed on the other side of the power line PL3. The capacitors ODC1 and ODC2 are electrically connected to the power line PL1 via the power line PL3 and the connection line CPL1.

The power line PL5 is disposed on one side of the power line PL6, and the capacitors ODC1 and ODC2 are disposed on the other side of the power line PL6. The capacitors ODC1 and ODC2 are electrically connected to the power line PL5 via the power line PL6 and the connection line.

Therefore, not only the cores 12 and 14 adjacent to the capacitors ODC1 and ODC2, but also the cores 11 and 13 disposed further away therefrom may be sufficiently subjected to an effect of the capacitors ODC1 and ODC2.

While the present disclosure has been particularly shown and described with reference to embodiments thereof, it will be understood by those of ordinary skill in the art that various changes in form and detail may be made therein without departing from the spirit and scope of the present disclosure as defined by the following claims.

What is claimed is:

1. A substrate, comprising:
a first layer including a first power line extending in a first direction and a second power line extending in the first direction;
a second layer disposed under the first layer, wherein the second layer includes a third power line extending in a second direction different from the first direction, and a fourth power line extending in the second direction;
a first via electrically connecting the first power line and the third power line to each other; and
a second via electrically connecting the second power line and the fourth power line to each other,
wherein a first voltage is transferred via the third power line, the first via, and the first power line,
wherein a second voltage is transferred via the fourth power line, the second via, and the second power line.

2. The substrate of claim 1, further comprising:
a first bump disposed on an upper surface of the first layer and electrically connected to the first power line; and
a second bump disposed on the upper surface of the first layer and electrically connected to the second power line.

3. The substrate of claim 1, further comprising:
a first plane disposed under the second layer,
wherein a first ball is disposed on a lower surface of the first plane and is electrically connected to the third power line via a third via.

4. The substrate of claim 3, wherein the first layer further includes a fifth power line extending in the first direction,
wherein the substrate further comprises a second plane disposed under the second layer,
wherein the second plane is spaced apart from the first plane,
wherein the first and second planes are positioned at a same vertical level,
wherein a second ball is disposed on a lower surface of the second plane and is electrically connected to the fifth power line.

5. The substrate of claim 1, wherein the first layer further includes a first ground line extending in the first direction and disposed between the first power line and the second power line.

6. The substrate of claim 1, wherein the first layer further includes a fifth power line that transmits the first voltage,
wherein the first power line, the second power line, and the fifth power line are sequentially arranged in a line along the first direction.

7. The substrate of claim 6, wherein the first power line and the fifth power line are connected to each other via a connection line,
wherein the connection line has a meandering shape bypassing the second power line.

8. The substrate of claim 7, wherein the first power line is disposed on one side of the fifth power line, and a die-side capacitor is disposed on another side of the fifth power line,
wherein the die-side capacitor is electrically connected to the first power line via the fifth power line and the connection line.

9. The substrate of claim 6, wherein a first core and a second core spaced apart from each other are disposed on the first layer,
wherein the first core is disposed on the first power line, and the second core is disposed on the fifth power line.

10. The substrate of claim 6, wherein the first layer further includes:
a sixth power line extending in the first direction and that transmits the first voltage; and
a seventh power line extending in the first direction and that transmits the second voltage,
wherein the first power line, the seventh power line, and the sixth power line are spaced apart from each other in the second direction and extend parallel to each other.

11. The substrate of claim 10, wherein a first core, a second core, and a third core included in a first processor and spaced apart from each other are disposed on the first layer,
wherein the first core is disposed on the first power line, the second core is disposed on the fifth power line, and the third core is disposed on the sixth power line.

12. The substrate of claim 11, wherein a fourth core and a fifth core included in a second processor different from the first processor are disposed on the first layer,
wherein the fourth core is disposed on the second power line, and the fifth core is disposed on the seventh power line.

13. The substrate of claim 1, wherein the first direction and the second direction are orthogonal to each other.

14. A substrate, comprising:
a first layer including a first power line extending in a first direction and that transmits a first voltage, and a second power line extending in the first direction and that transmits a second voltage;
a second layer disposed under the first layer, wherein the second layer includes a third power line extending in a second direction different from the first direction, and a fourth power line extending in the second direction;
a first via electrically connecting the first power line and the third power line to each other;
a second via electrically connecting the second power line and the fourth power line to each other;
a first bump disposed on an upper surface of the first layer and electrically connected to the first power line; and
a second bump disposed on the upper surface of the first layer and electrically connected to the second power line,
wherein the first layer further includes a fifth power line that transmits the first voltage,
wherein the first power line, the second power line, and the fifth power line are sequentially arranged in a line along the first direction,
wherein the first power line and the fifth power line are connected to each other via a connection line, wherein the connection line has a meandering shape bypassing the second power line,
wherein the first power line is disposed on one side of the fifth power line, and a die-side capacitor is disposed on another side of the fifth power line,
wherein the die-side capacitor is electrically connected to the first power line via the fifth power line and the connection line.

15. A semiconductor device, comprising:
a board having a first area and a second area defined therein, wherein the first and second areas are distinct from each other;
a semiconductor package disposed in the first area; and
a power management chip disposed in the second area,
wherein the semiconductor package operates using a first voltage and a second voltage different from the first voltage, and the power management chip operates using the first voltage,
wherein the board includes:
a first layer including a first power line extending in a first direction and a second power line extending in the first direction;
a second layer disposed under the first layer and including a third power line extending in a second direction different from the first direction and a fourth power line extending in the second direction;
a first via electrically connecting the first power line and the third power line to each other; and
a second via electrically connecting the second power line and the fourth power line to each other,
wherein the first voltage is transferred via the third power line, the first via, and the first power line, and the second voltage is transferred via the fourth power line, the second via, and the second power line.

16. The semiconductor device of claim 15, wherein the first power line is disposed in the first area,
wherein the first layer further includes a fifth power line disposed in the second area,
wherein the third power line extends from the first area to the second area and is further connected to the fifth power line via a third via.

17. The semiconductor device of claim 15, further comprising:
a first plane disposed under the second layer,
wherein the first plane is electrically connected to the fourth power line via a third via.

18. The semiconductor device of claim 17, further comprising:
a second plane disposed under the first plane and disposed across the first area and the second area,
wherein the third power line extends from the first area to the second area,
wherein the second plane is electrically connected to a portion of the third power line in the first area via a fourth via and is electrically connected to the portion of the third power line in the first area via a fifth via.

19. The semiconductor device of claim 18, further comprising:
a ground plane disposed under the first plane and on top of the second plane.

20. The semiconductor device of claim 15, wherein the semiconductor package includes:
a first processor that operates using the first voltage and including a first plurality of cores; and
a second processor that operates using the second voltage and including a second plurality of cores.
